(19) United States
(12) Patent Application Publication
(10) Pub. No.: US 2005/0092508 A1
(43) Pub. Date: May 5, 2005

(54) Circuit device

(76) Inventors: Atsushi Kato, Gunma (JP); Atsushi Nakano, Gunma (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 10/947,652

(22) Filed: Sep. 22, 2004

(30) Foreign Application Priority Data
Sep. 24, 2003 (JP) P.2003-331636

(51) Int. Cl. H05K 5/06

(52) U.S. Cl. 174/52.2

(57) ABSTRACT

Provided is a circuit device having a structure for suppressing a leakage current between patterns. A circuit device of the embodiments has a constitution in which a circuit element and desired conductive patterns are integrally resin-molded. Furthermore, the circuit device includes: a first conductive pattern connected to a high impedance input terminal of the circuit element; a second conductive pattern provided close to the first conductive pattern; and a guard conductive pattern extended between the first and second conductive patterns. Accordingly, the circuit device is constituted to prevent a leakage current between the first and second conductive patterns.

### BACKGROUND OF THE INVENTION

Priority is claimed to Japanese Patent Application Number JP2003-331636 filed on Sep. 24, 2003, the disclosure of which is incorporated herein by reference in its entirety.

1. Field of the Invention

The present invention relates to a circuit device, more particularly to a circuit device having a structure for suppressing a leakage current between conductive patterns.

2. Description of the Related Art

With reference to FIGS. 6A and 6B, a constitution of a conventional semiconductor device 100 will be described. FIG. 6A is a plan view of the semiconductor device 100 and FIG. 6B is a section view thereof.

With reference to FIG. 6A, a land 102 made of a conductive material is formed at the central portion of the semiconductor device 100 and one end of each of a plurality of leads 101 is made close to the periphery of the land 102. The one end of each of the plurality of leads 101 is electrically connected to a semiconductor element 104 by a thin metal wire 105 and the other end thereof is exposed from a sealing resin 103. The sealing resin 103 has a function to seal the semiconductor element 104, the land 102 and the leads 101 and to support them collectively.

### SUMMARY OF THE INVENTION

However, in the semiconductor device 100 described above, if the leads 101 whose potentials are significantly different from each other, are close to each other, a leakage current may occur therebetween. Particularly, when an impedance of one of the leads 101 is high, this leakage current flows into the lead 101 having the high impedance. Thus, there arises a problem that characteristics of an electric circuit formed in the device are changed.

The present invention was made in view of the above described problem. A principal object of the present invention is to provide a circuit device having a structure for suppressing a leakage current between patterns.

A circuit device of the preferred embodiments of the present invention, which has a circuit element and a conductive pattern, includes: a first conductive pattern connected to a high impedance input terminal of the circuit element; a second conductive pattern provided close to the first conductive pattern; and a guard conductive pattern extended between the first and second conductive patterns.

Furthermore, in the preferred embodiments, the conductive pattern having a potential closest to that of the first conductive pattern is adopted as the guard conductive pattern.

Furthermore, in the preferred embodiments, the first conductive pattern is surrounded by the guard conductive pattern.

Furthermore, the preferred embodiment further includes a multi-layered wiring structure including a first and second wiring layers and the guard conductive pattern is formed in one of the first and second wiring layers.

Furthermore, in the preferred embodiment, the circuit element and the conductive pattern are sealed by a sealing resin while exposing a rear surface of the conductive pattern.

Furthermore, in the preferred embodiment, the first conductive pattern is connected to an input terminal of an OP amplifier.

Furthermore, in the preferred embodiment, the guard conductive pattern is connected to a ground potential.

According to the circuit device of the preferred embodiment of the present invention, by extending the guard conductive pattern between the conductive patterns having different potentials from each other, a leakage current in the device can be suppressed. Therefore, characteristics of an electric circuit built into the device can be improved. Furthermore, a mounting board can have a constitution in which measures against the leakage current are omitted. Thus, a pattern structure of the mounting board can be simplified.

### BRIEF DESCRIPTION OF THE DRAWINGS

FIGS. 1A, 1B and 1C are a plan view, a section view and a section view, respectively, showing a circuit device of a preferred embodiment.

FIGS. 2A and 2B are a plan view and a section view, respectively, showing a circuit device of the preferred embodiment.

FIGS. 3A and 3B are a plan view and a section view, respectively, showing a circuit device of the preferred embodiment.

FIG. 4 is a section view showing a circuit device of the preferred embodiment.

FIG. 5 is a section view showing the circuit device of the preferred embodiment.

FIGS. 6A and 6B are a plan view and a section view, respectively, showing a conventional circuit device.

### DESCRIPTION OF THE EMBODIMENTS

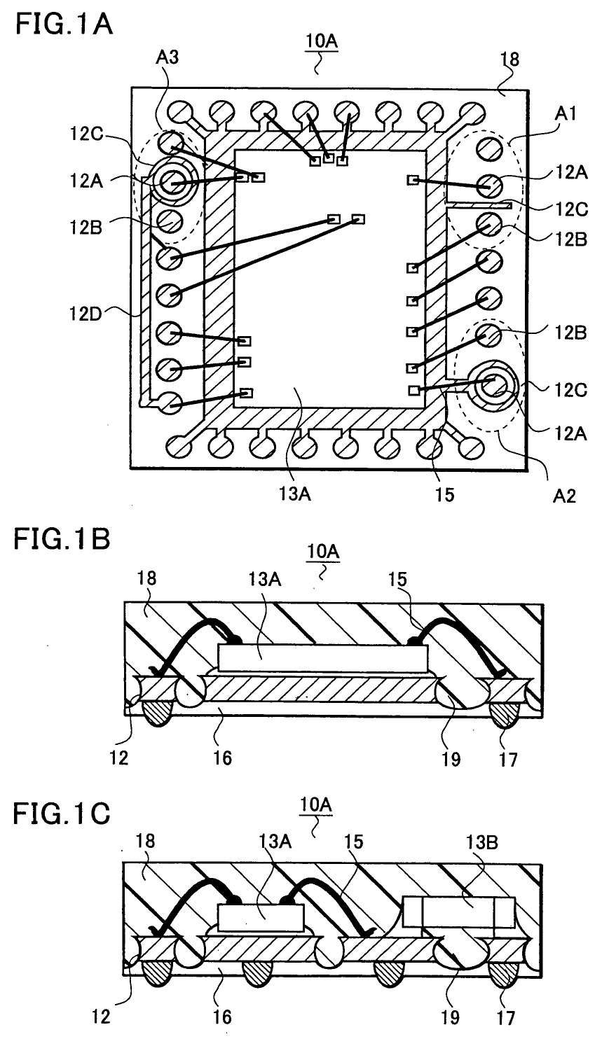

With reference to FIGS. 1A to 1C, description will be given of a constitution of a circuit device 10 of this embodiment. FIG. 1A is a plan view of the circuit device 10A and FIGS. 1B and 1C are section views thereof.

With reference to FIG. 1A, the circuit device 10A of this embodiment has a constitution in which a circuit element 13 and desired conductive patterns 12 are integrally resin-molded. Furthermore, the circuit device 10 includes: a first conductive pattern 12A connected to a high impedance input terminal of the circuit element 13; a second conductive pattern 12B provided close to the first conductive pattern; and a guard conductive pattern 12C extended between the first and second conductive patterns. Accordingly, the circuit device 10 is configured to prevent a leakage current between the first and second conductive patterns 12A and 12B. Details of respective components and related constitutions will be described below.

The first conductive pattern 12A, the second conductive pattern 12B and the guard conductive pattern 12C are made of a metal such as copper. These conductive patterns 12 are separated by a sealing resin 18 filled in an isolation trench 19 formed by etching.

Here, the circuit element 13 is formed of a semiconductor element 13A and a chip element 13B. An active element such as an LSI chip, a bare transistor chip, and a diode can be adopted as the circuit element 13. Furthermore, a passive element such as a chip resistor, a chip capacitor, and an inductor can be also adopted as the circuit element 13. The semiconductor element 13A has its back die bonded to a die pad formed of the conductive pattern 12. Electrodes on a surface of the semiconductor element 13A and bonding pads formed of the conductive patterns 12 are electrically connected to each other through thin metal wire 15. Moreover, it is also possible to connect the semiconductor element 13A face down. The chip element 13B has electrodes on its both ends, which are die bonded to the conductive patterns 12 by use of a brazing material such as soft solder.

The sealing resin 18 is made of thermoplastic resin formed by injection molding or thermosetting resin formed by transfer molding. The sealing resin 18 has a function to seal the entire device as well as a function to mechanically support the entire device. With reference to FIG. 1B, the sealing resin 18 seals the circuit element 13, the thin metal wire 15 and the conductive patterns 12 while exposing rear surfaces of the conductive patterns 12 to the outside.

Moreover, a bottom surface of the sealing resin 18, on which the conductive patterns 12 are exposed, is covered with a resist 16 made of resin except spots where external electrodes 17 are formed. The external electrodes 17 are made of a brazing material such as soft solder and formed on the rear surfaces of the conductive patterns 12.

With reference to FIG. 1A, a constitution of the conductive patterns 12 for suppressing the leakage current, which is an advantage of the preferred embodiment, will be concretely described.

With reference to a first region A1 in FIG. 1A, the first conductive pattern 12A is electrically connected to the semiconductor element 13A through the thin metal wire 15. This first conductive pattern 12A is a conductive pattern having an impedance higher than those of the other conductive patterns. As an example, the first conductive pattern 12A can be connected to an inverting input part of an OP amplifier (Operational Amplifier) or a non-inverting input part thereof. Accordingly, the impedance of the first conductive pattern 12A is as extremely high as, for example, about several hundred kilo Ω to several mega Ω. In other words, a current flowing through the first conductive pattern 12A becomes extremely small. To be more specific, a value of the current flowing through the first conductive pattern 12A connected to an input terminal of the OP amplifier is, for example, about several microamperes. Here, the first conductive pattern 12A is connected to the semiconductor element 13A that is an IC. However, the first conductive pattern 12A may be connected to the other circuit element 13 described above.

The second conductive pattern 12B is provided close to the first conductive pattern 12A described above. This second conductive pattern 12B is a conductive pattern having a potential different from that of the first conductive pattern 12A described above. For example, a pattern having a potential higher than that of the first conductive pattern 12A or a pattern having a potential lower than that of the first conductive pattern 12A can be adopted as the second conductive pattern 12B. For example, a pattern to which a voltage of several tens of volts is applied is adopted as the second conductive pattern 12B.

As described above, the first and second conductive patterns 12A and 12B have potentials different from each other. Therefore, this potential difference may cause a leakage current to flow into the first conductive pattern 12A from the second conductive pattern 12B. Considering the case where the impedance of the first conductive pattern 12A is high and the potential of the second conductive pattern 12B is high, this problem is noticeable. This is because the leakage current may trigger a malfunction of the OP amplifier. Consequently, in the preferred embodiment, the problem described above is solved by the guard conductive pattern 12C.

The guard conductive pattern 12C is a conductive pattern which extends between the first and second conductive patterns 12A and 12B and suppresses occurrence of the leakage current between the first and second conductive patterns 12A and 12B. Here, the guard conductive pattern 12C linearly extends between the first and second conductive patterns 12A and 12B. As the guard conductive pattern 12C, a conductive pattern having a potential closer to that of the first conductive pattern 12A than that of the second conductive pattern 12B is adopted. It is more preferable that the conductive pattern 12 having a potential closest to that of the first conductive pattern 12A among the conductive patterns 12 included in the circuit device 10A is adopted as the guard conductive pattern 12C. Furthermore, as the guard conductive pattern 12C, the conductive pattern 12 electrically connected to the circuit element 13 built into the device can be adopted.

When there is no conductive pattern 12 having a potential close to that of the first conductive pattern 12A in the circuit device 10A, a potential close to that of the first conductive pattern 12A can be drawn from the outside of the circuit device. To be more specific, the potential can be drawn to the guard conductive pattern 12C through the external electrode 17 from a conductive path in the board on which the circuit device 10A is mounted. In the case as described above, the guard conductive pattern 12C does not always have to be connected to the circuit element 13. Therefore, in such a case, the guard conductive pattern 12C can be formed of only a wiring part extending between the first and second conductive patterns 12A and 12B.

The case where the input terminal of the OP amplifier is adopted as the first conductive pattern 12A is considered. When an input potential of the OP amplifier is set to be small, the conductive pattern 12 connected to the ground potential can be adopted as the guard conductive pattern 12C. According to the constitution described above, even if a leakage current flows into the first conductive pattern 12A from the second conductive pattern 12B having a high potential, the leakage current is absorbed by the guard conductive pattern 12C. Moreover, as described above, since the first conductive pattern 12A and the guard conductive pattern 12C have the potentials close to each other, there is basically no occurrence of leakage currents therebetween.

With reference to a second region A2 in FIG. 1A, description will be given of another constitution for solving the problem caused by the leakage current. Here, the guard conductive pattern 12C is formed so as to surround a periphery of the first conductive pattern 12A. According to this constitution, an effect of preventing the flow of the leakage current into the first conductive pattern 12A can be further enhanced. Moreover, even if the first conductive pattern 12A is surrounded by the second conductive pattern 12B having a different potential, according to the constitution described above, the flow of the leakage current can be prevented. Here, the ring-shaped guard conductive pattern 12C is electrically connected to the circuit element 13. However, as described above, a potential can be drawn from the outside of the circuit device 10A.

With reference to a third region A3 in FIG. 1A, description will be given of another constitution for solving the problem caused by the leakage current. Here, the guard conductive pattern 12C is drawn from a distant conductive pattern 12 through a wiring part 12D. There is a case where the conductive pattern having a potential close to that of the first conductive pattern 12A is distant from the first conductive pattern 12A. In this case, the guard conductive pattern 12C can be formed by extending the wiring part 12D. Here, instead of the wiring part 12D formed of the conductive pattern 12, thin metal wire 15 can be also used.

With reference to FIG. 1C, the semiconductor element 13A and the chip element 13B are adopted as the circuit elements 13. As described above, a plurality of the circuit elements 13 can be also built into the circuit device 10A.

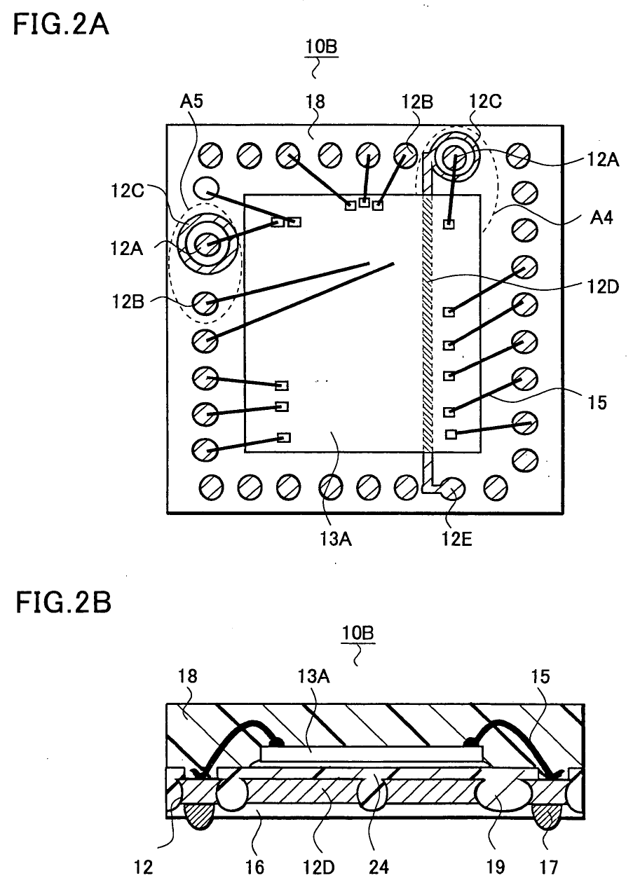

With reference to FIGS. 2A and 2B, description will be given of a constitution of a circuit device 10B of another embodiment. FIG. 2A is a plan view of the circuit device 10B and FIG. 2B is a section view thereof. A basic constitution of the circuit device 10B shown in FIGS. 2A and 2B is similar to that of the circuit device 10A shown in FIGS. 1A to 1C and is different therefrom in an extending structure of the conductive pattern 12. This difference will be mainly described.

With reference to a fourth region A4 in FIG. 2A, a guard conductive pattern 12C of this embodiment extends below the semiconductor element 13A as the circuit element 13. A conductive pattern 12E having a potential close to that of the first conductive pattern 12A positioned in this region A4 is positioned across the semiconductor element 13A from the first conductive pattern 12A. To be more specific, the first conductive pattern 12A and the conductive pattern 12E having the potential close to that of the first conductive pattern 12A are positioned in the vicinity of peripheral portions of the circuit device 10B, which are opposite to each other. In the preferred embodiment, the guard conductive pattern 12C and the conductive pattern 12E can be electrically connected to each other through the wiring part 12D extending below the semiconductor element 13A. Specifically, the pattern is not routed around the region where the circuit element 13 is disposed, and the conductive patterns 12 can be linearly connected to each other.

With reference to a fifth region A5 in FIG. 2A, the guard conductive pattern 12C extending between the first and second conductive patterns 12A and 12B is not electrically connected to the circuit element 13. Specifically, the guard conductive pattern 12C forms a portion extending as the wiring part and is connected to the outside of the circuit device 10B through the external electrode 17. According to this constitution, even if there is no conductive pattern 12 having a potential close to that of the first conductive pattern 12A among the conductive patterns 12 inside the circuit device 10B, the potential can be obtained from the outside.

With reference to FIG. 2B, a cross-sectional structure of the circuit device 10B will be described. The conductive patterns 12 are covered with a covering resin 24 and the semiconductor element 13A is die bonded to a surface of this covering resin 24. According to the constitution described above, the conductive patterns 12 can be routed below the region where the circuit element 13 such as the semiconductor element 13A is disposed. Thus, wiring density can be improved. Moreover, upper surfaces of the conductive patterns 12 in spots to be electrically connected to the circuit element 13 are exposed from the covering resin 24. Here, upper surfaces of the conductive patterns 12 in regions to be bonding pads are exposed from the covering resin 24.

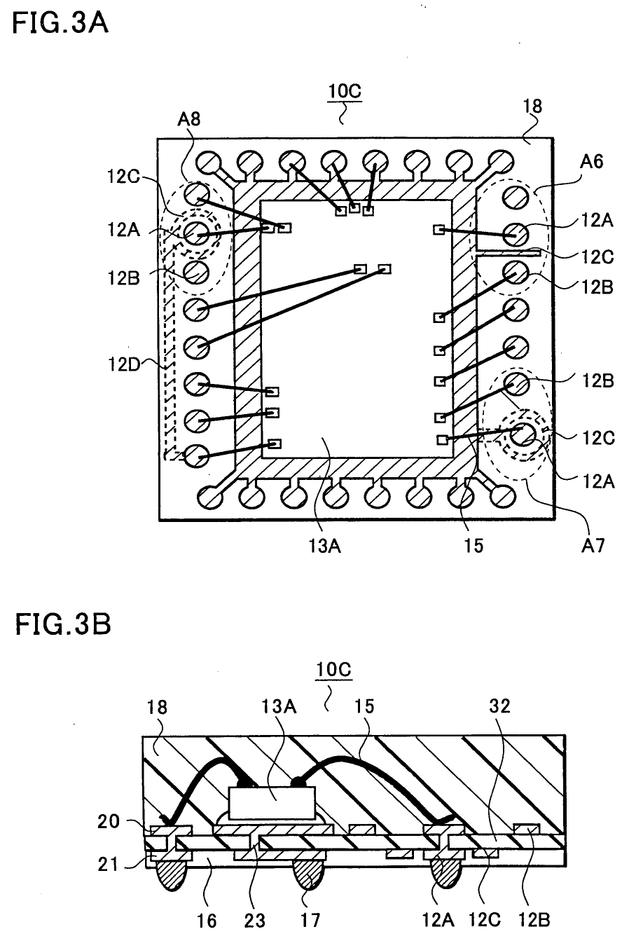

With reference to FIGS. 3A and 3B, description will be given of a constitution of a circuit device 10C of another embodiment. FIG. 3A is a plan view of the circuit device 10C and FIG. 3B is a section view thereof. A basic constitution of the circuit device 10C shown in FIGS. 3A and 3B is similar to that of the circuit device 10A shown in FIGS. 1A to 1C and is different therefrom in having a plurality of wiring layers. This difference will be mainly described.

With reference to FIG. 3A, a first wiring layer 20 that is an upper wiring layer is indicated by a solid line, and a second wiring layer 21 that is a lower wiring layer is indicated by a dashed line. With reference to a sixth region A6 in FIG. 3A, the first and second conductive patterns 12A and 12B and the guard conductive pattern 12C are formed of the first wiring layer 20. Accordingly, a leakage current occurring between the first and second conductive patterns 12A and 12B, which are formed of the first wiring layer 20, can be suppressed by the guard conductive pattern 12C similarly formed of the first wiring layer 20.

With reference to a seventh region A7 in FIG. 3A, here, the first and second conductive patterns 12A and 12B are formed of the first wiring layer 20 and the guard conductive pattern 12C is formed of the second wiring layer 21. Specifically, with reference to FIG. 3B, suppression of the leakage current in the first wiring layer 20, the upper layer, can be performed by the guard conductive pattern 12C formed of the second wiring layer 21, the lower layer. Here, the guard conductive pattern 12C may be one electrically connected to one of the first wiring layer 20 and the circuit element 13 through a connection part 23. Furthermore, here, the guard conductive pattern 12C may be one electrically connected to neither of the first wiring layer 20 and the circuit element 13.

With reference to an eighth region A8 in FIG. 3A, the first and second conductive patterns 12A and 12B are formed of the first wiring layer 20. The guard conductive pattern 12C is routed by the wiring part 12D formed of the second wiring layer 21. Therefore, even if the conductive pattern 12 having a potential close to that of the first conductive pattern 12A is positioned distant from the first conductive pattern 12A, the pattern can be routed by the wiring part 12D formed in the second wiring layer 21.

With reference to FIG. 3B, here, the circuit device 10C has two wiring layers including the first and second wiring layers 20 and 21, which are laminated with an insulating layer 32 interposed therebetween. The first and second wiring layers 20 and 21 are electrically connected to each other through the connection parts 23 penetrating the insulating layer 32. Note that, as a structure of the wiring layers, a wiring structure including three layers or more is also possible.

In the foregoing description, the structure for suppressing the leakage current in the first wiring layer 20, the upper layer, was described. Meanwhile, according to a structure similar to that described above, a leakage current in the second wiring layer 21, the lower layer, can be suppressed. Specifically, by forming the guard conductive pattern 12C in the first wiring layer 20, the leakage current in the second wiring layer 21 can be prevented. Furthermore, by providing the guard conductive pattern 12C in the second wiring layer 21, the leakage current in the first wiring layer 20 can be also prevented. Furthermore, it is also possible to form the guard conductive pattern 12C having a shape similar to that described above in both of the first and second wiring layers 20 and 21. Thus, the effect of preventing the leakage current can be further enhanced.

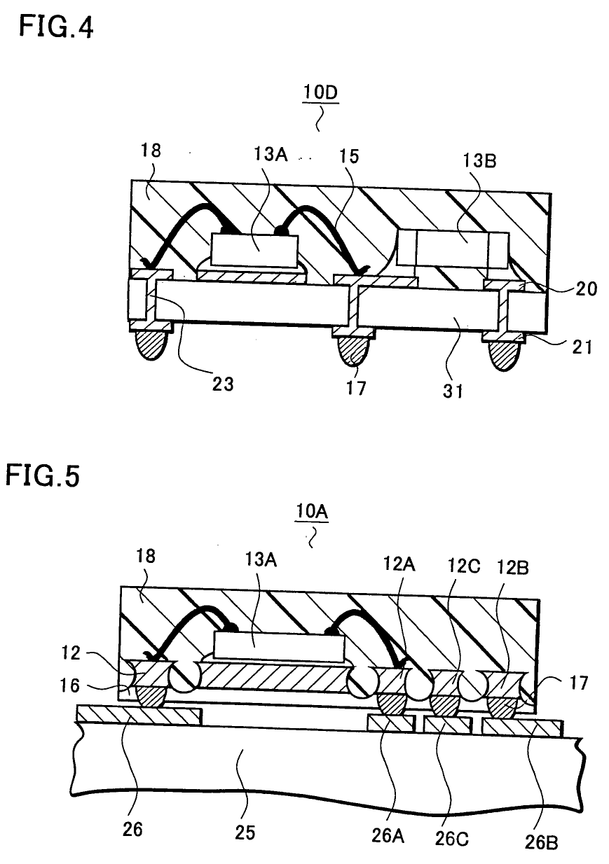

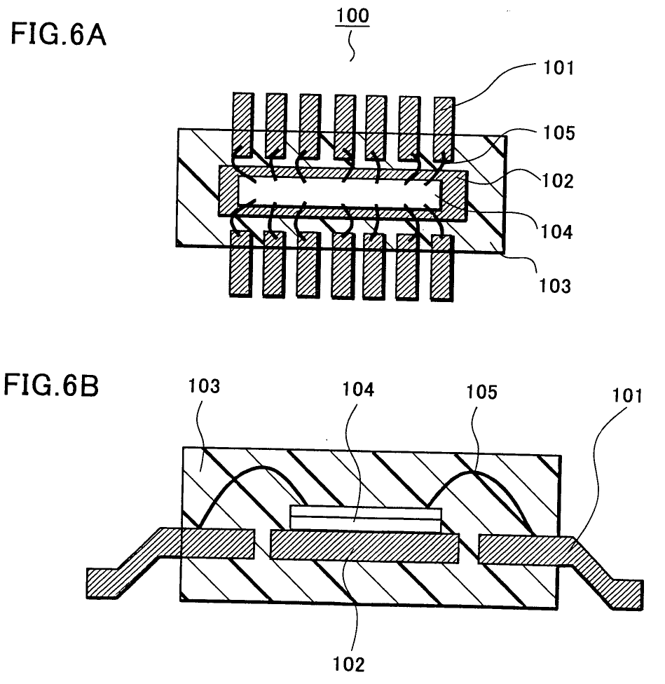

With reference to FIG. 4, description will be given of a constitution of a circuit device 10D of another embodiment. A basic constitution of the circuit device 10D, the cross section of which is shown in FIG. 4, is similar to that of the circuit device 10C shown in FIGS. 3A and 3B and is different therefrom in having a supporting board 31. As this supporting board 31, a well-known board, including a board made of resin board such as a glass epoxy board, a ceramic board, a metal board can be used.

With reference to a section view of FIG. 5, description will be given of a constitution of the circuit device 10A mounted on a mounting board 25. Here, the description will be given by using the circuit device 10A shown in FIGS. 1A to 1C. The following constitution is applicable to the circuit devices 10 described by use of the other drawings.

The circuit device 10A is die bonded to conductive paths 26 formed on a surface of the mounting board 25 with the external electrodes 17 interposed therebetween, the external electrodes 17 being formed on the rear surfaces of the conductive patterns 12 and made of a brazing material. The first conductive pattern 12A is connected to a first conductive path 26A through the external electrode 17. The second conductive pattern 12B is connected to a second conductive path 26B through the external electrode 17. Furthermore, the guard conductive pattern 12C is connected to a guard conductive path 26C on the mounting board 25 side through the external electrode 17. Here, the guard conductive path 26C on the mounting board 25 side does not always have to be connected to the guard conductive pattern 12C but may be connected to another portion having a potential close to that of the first conductive pattern 12A.

By providing the guard conductive pattern 12C in the circuit device 10A, the flow of the leakage current into the first conductive pattern 12A can be suppressed. Furthermore, by providing the guard conductive path 26C also on the mounting board 25 side, the effect described above can be enhanced. To be more specific, even if dust and the like adhere to surfaces of the conductive paths 26, a leakage current occurring between the conductive paths 26 can be suppressed.

1. A circuit device which has a circuit element and a conductive pattern, comprising:
a first conductive pattern connected to a high impedance input terminal of the circuit element;
a second conductive pattern provided close to the first conductive pattern; and
a guard conductive pattern extended between the first and second conductive patterns.

2. The circuit device according to claim 1, wherein the conductive pattern having a potential closest to that of the first conductive pattern is adopted as the guard conductive pattern.

3. The circuit device according to claim 1, wherein the first conductive pattern is surrounded by the guard conductive pattern.

4. The circuit device according to claim 1, further comprising:
a multi-layered wiring structure including a first and second wiring layers,
wherein the guard conductive pattern is formed in one of the first and second wiring layers.

5. The circuit device according to claim 1, wherein the circuit element and the conductive pattern are sealed by a sealing resin while exposing a rear surface of the conductive pattern.

6. The circuit device according to claim 1, wherein the first conductive pattern is connected to an input terminal of an OP amplifier.

7. The circuit device according to claim 1, wherein the guard conductive pattern is connected to a ground potential.
